(19) United States
(12) Patent Application Publication
(10) Pub. No.: US 2014/0175232 A1
(43) Pub. Date: Jun. 26, 2014

(54) MOUNTING APPARATUS FOR DATA STORAGE DEVICE

(71) Applicants: HON HAI PRECISION INDUSTRY CO., LTD., New Taipei (TW); HONG FU JIN PRECISION INDUSTRY (ShenZhen) CO., LTD., Shenzhen (CN)

(72) Inventor: XIU-QUAN HU, Shenzhen (CN)

(73) Assignees: HON HAI PRECISION INDUSTRY CO., LTD., New Taipei (TW); HONG FU JIN PRECISION INDUSTRY (ShenZhen) CO.,LTD., Shenzhen (CN)

(21) Appl. No.: 13/953,938

(22) Filed: Jul. 30, 2013

(30) Foreign Application Priority Data
Dec. 22, 2012 (CN) 2012105616487

(51) Int. Cl. H05K 7/14

(52) U.S. Cl. CPC H05K 7/14
USPC 248/68.1; 248/299.1; 248/223.41

(57) ABSTRACT

A mounting apparatus includes a first bracket securing a first data storage device, a second bracket securing a second data storage device, and a rotating member secured to the first bracket. The second bracket is rotatably mounted to the rotating member, so that the first data storage device can be removed from the first bracket by rotating the second bracket relative to the first bracket without removing the second bracket from the first bracket.

### BACKGROUND

1. Technical Field

The present disclosure relates to mounting apparatuses, and particularly to a mounting apparatus for a data storage device.

2. Description of Related Art

In electronic devices, such as servers, a number of data storage devices are used. Generally, each data storage device is secured to a bracket, and the brackets are secured together with screws and stacked one by one. When a lower data storage device is needed, the brackets above the lower data storage device should be removed first, which is inconvenient and time consuming. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting apparatus.

FIG. 2 is an isometric view of a rotating member of the mounting apparatus of FIG. 1.

FIG. 3 is an assembled, isometric view of the mounting apparatus of FIG. 1, with a first installation piece of an installation member partially cut-away to allow a view of a fastener.

FIG. 4 is another assembled, isometric view of the mounting apparatus of FIG. 1.

FIG. 5 is an enlarged view of a circled portion V of FIG. 4.

FIG. 6 is similar to FIG. 4, but viewed from a different aspect.

FIG. 7 is an enlarged view of a circled portion VII of FIG. 6.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

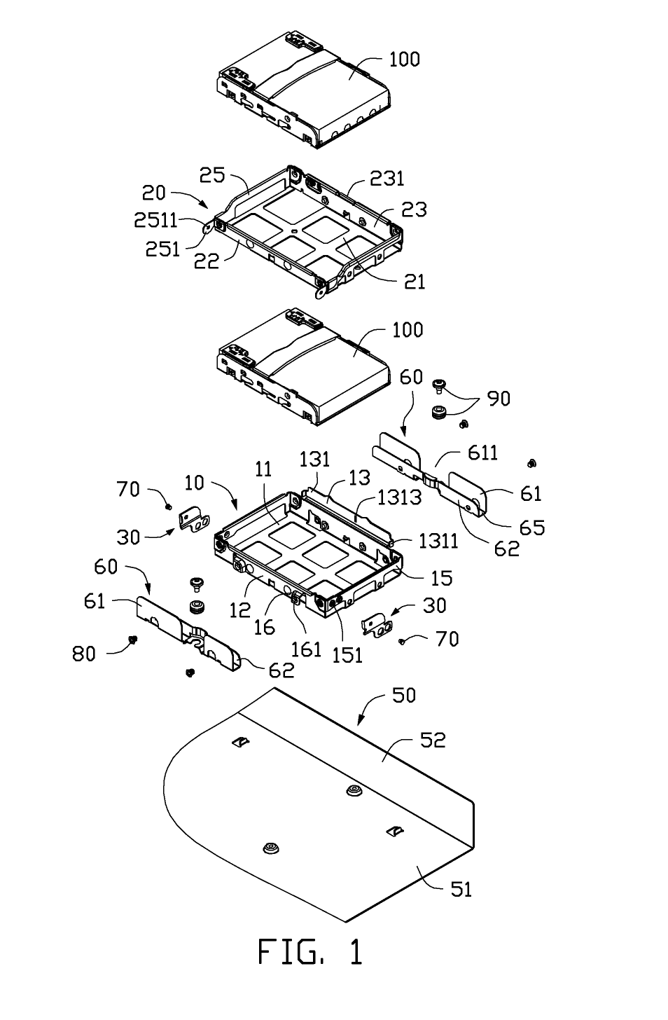

FIG. 1 shows one embodiment of a mounting apparatus for securing two data storage devices 100. The mounting apparatus includes a first bracket 10, a second bracket 20, and two rotating members 30. In one embodiment, each data storage device 100 is a hard disk drive.

The first bracket 10 includes a first bottom wall 11, a first front wall 12, a first rear wall 13, and two first sidewalls 15 connecting the first front wall 12 to the first rear wall 13. In one embodiment, the first front wall 12 is substantially parallel to the first rear wall 13, and the first bottom wall 11 is substantially perpendicular to first front wall 12 and the two first sidewalls 15. Two protrusions 16 extend from each of the first front wall 12 and the first rear wall 13. Each protrusion 16 defines an installation hole 161. A mounting plate 131 extends upwards from the first rear wall 13. A flange 1311 extends from each of two side edges of the mounting plate 131. The mounting plate 131 defines a mounting slot 1313. In one embodiment, the mounting plate is substantially “L” shaped, the flange 1311 is substantially perpendicular to the mounting plate 131, and an extending direction of the mounting slot 1313 is substantially perpendicular to the first bottom wall 11. Each first sidewall 15 defines two mounting holes 151 for securing the rotating member 30.

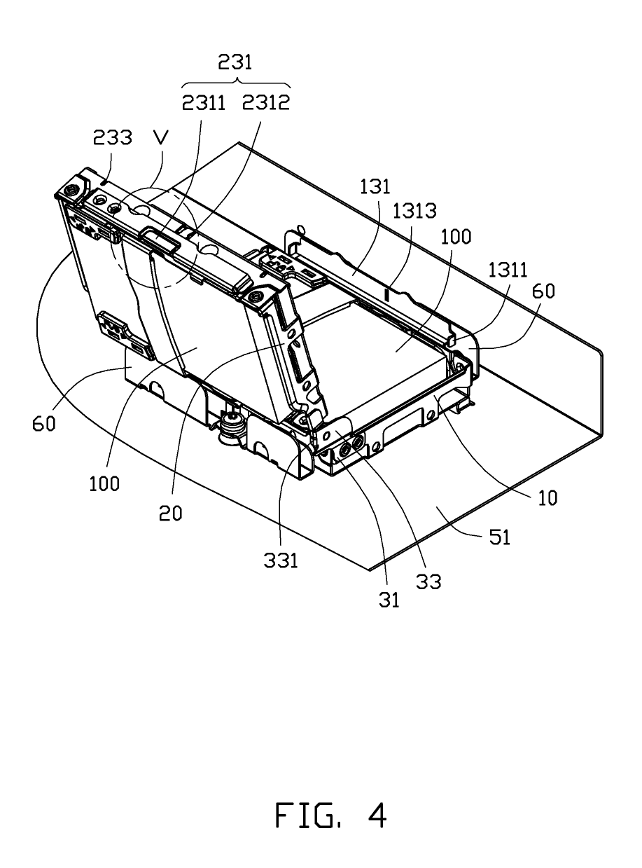

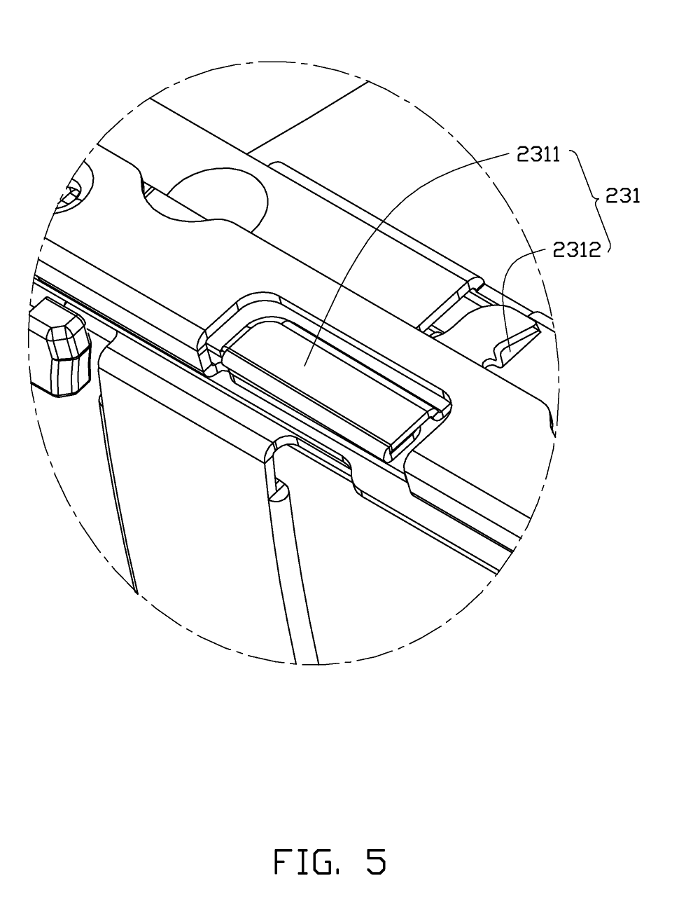

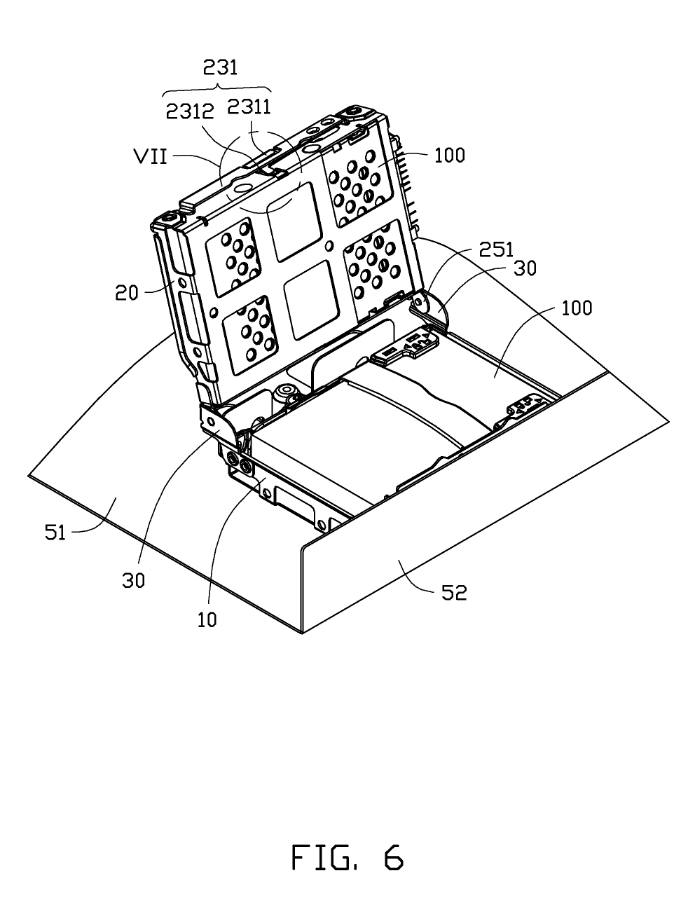

The second bracket 20 includes a second bottom wall 21, a second front wall 22, a second rear wall 23, and two second sidewalls 25 connecting the second front wall 22 to the second rear wall 23. In one embodiment, the second front wall 22 is substantially parallel to the second rear wall 23, and the second bottom wall 21 is substantially perpendicular to second front wall 22 and the two second sidewalls 25. Two limiting slots 233 (shown in FIGS. 4 and 6) are defined in the second rear wall 23 and extend to the second front wall 22. In one embodiment, each limiting slot 233 is “L” shaped. A pivoting piece 251 extends from an intersection edge of the second front wall 22 and each second sidewall 25. The pivoting piece 251 defines a pivoting hole 2511. In one embodiment, the pivoting piece 251 is substantially perpendicular to the second front wall 22. Referring to FIGS. 4-6, a latching plate (not labeled) extends from a side of the second rear wall 23 back to the second front wall 22. A first end of the latching plate is riveted to the second rear wall 23, and a second end of the latching plate includes a resilient portion 231. The resilient portion 231 includes an operation piece 2311 and a latching piece 2312 extending outwards from the operation piece 2311. The latching piece 2312 can engage in the mounting slot 1313. The operation piece 2311 is operable to elastically deform the resilient portion 231 to disengage the latching piece 2312 from the mounting slot 1313.

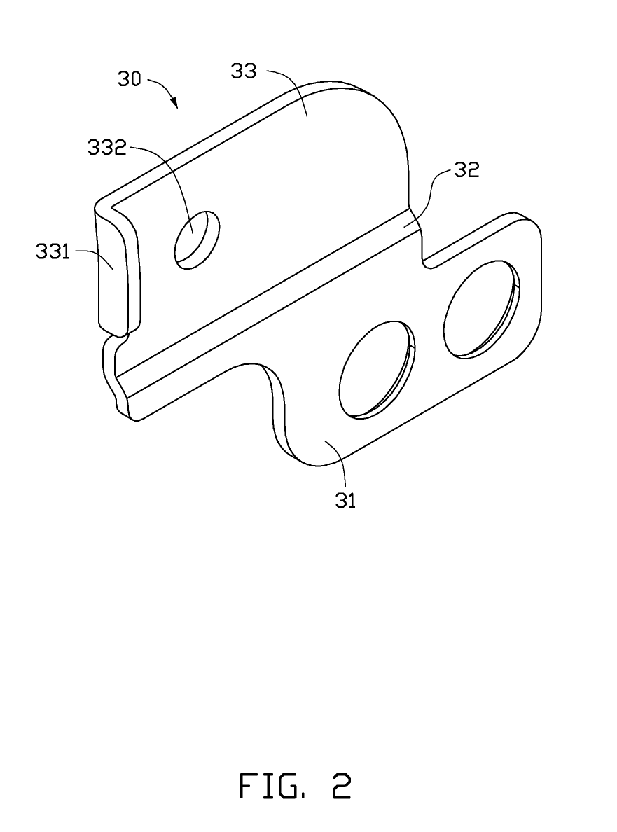

FIGS. 1 and 2 show each rotating member 30 including a mounting piece 31, a connecting piece 32, and a positioning piece 33. The mounting piece 31 and the positioning piece 33 extend from opposite edges of the connecting piece 32. In one embodiment, the mounting piece 31 is substantially parallel to the positioning piece 33 and substantially perpendicular to the connecting piece 32, and the positioning piece 33 is substantially perpendicular to the connecting piece 32. A length of the positioning piece 33 is greater than a length of the mounting piece 31. The positioning piece 33 defines a positioning hole 332. A limiting piece 331 extends from a side edge of the positioning piece 33. In one embodiment, the limiting piece 331 is substantially perpendicular to the positioning piece 33 and the connecting piece 32.

The mounting apparatus further includes a chassis 50 and two installation members 60.

The chassis 50 includes a bottom plate 51 and a side plate 52 substantially perpendicular to the bottom plate 51.

Each installation member 60 includes a first installation piece 61 and a second installation piece 62. In one embodiment, the first installation piece 61 is substantially parallel to the second installation piece 62. A cable groove 65 is defined between the first installation piece 61 and the second installation piece 62. The first installation piece 61 defines a cutout 611 for a cable passing through. The second installation 62 is for securing the first bracket 10.

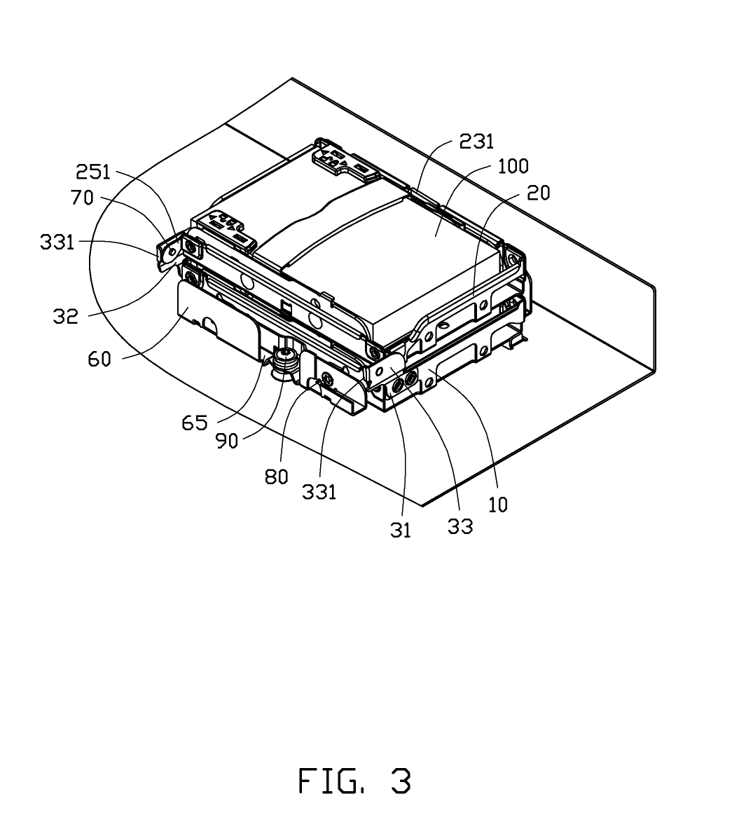

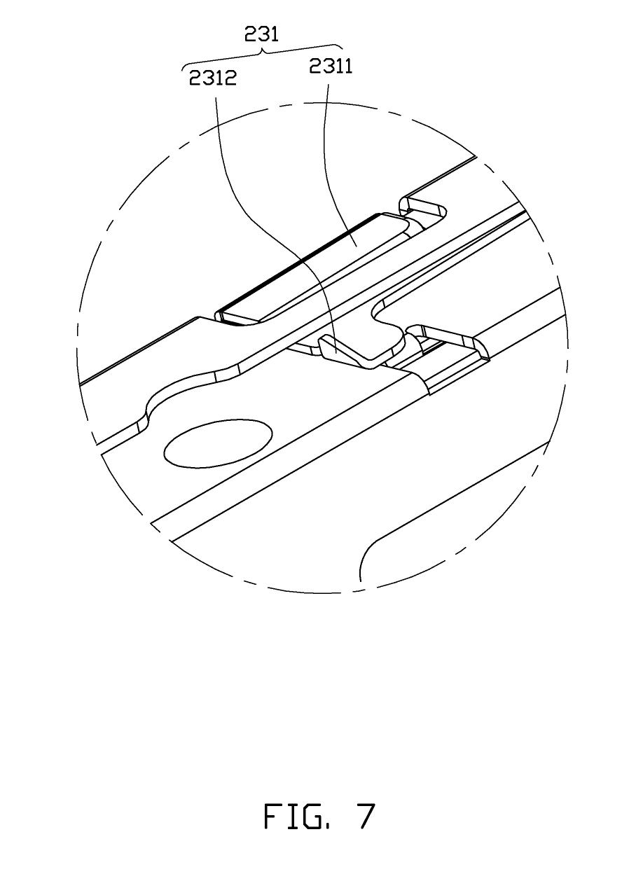

FIGS. 3-7 show that, in assembly, each installation member 60 is secured to the bottom plate 51 by a plurality of locking members 90, such as screws. The first bracket 10 is placed between the two installation members 60. The first front wall 12 and the first rear wall 13 is secured to the second installation piece 62 of one of the two installation members 60 with two screws 80. One of the two data storage devices 100 is secured to the first bracket 10. The pivoting piece 31 is secured to the first sidewall 15. The positioning piece 33 extends out of the first sidewall 15 away from the first rear wall 13 along a direction substantially perpendicular to the first rear wall 13. The second bracket 20 is moved to be adjacent to the first bracket 10, and the pivoting hole 2511 is aligned with the positioning hole 332. A pivoting shaft 70 is inserted through the positioning hole 332 and the pivoting hole 2511, and thus the pivoting piece 251 is pivotably mounted to the positioning piece 33. Thus, the second bracket 20 is rotatable relative to the first bracket 10 about the pivoting shaft 70. The second bracket 20 is rotated towards the first bracket 10 until the resilient portion 231 is elastically deformed and the latching piece 2312 is aligned with the mounting slot 1313. The resilient portion 231 rebounds to engage the latching piece 2312 in the mounting slot 1313. In this position, the flange 1311 is inserted in the limiting slot 233. Another data storage device 100 is then secured to the second bracket 20.

In disassembly, the resilient portion 231 is elastically deformed to disengage the latching piece 2312 from the mounting slot 1313. The second bracket 20 is rotatable towards the first bracket 10, and then the data storage device 100 can be removed from the first bracket without disassembling the second bracket 20. The limiting piece 331 and the connecting piece 32 are used for abutting the pivoting piece 251 when the second bracket 20 is rotated away from the first bracket 10, to prevent the second bracket 20 from rotating too far and to hold the pivoting piece 251, preventing the pivoting piece 251 from breaking.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A mounting apparatus, comprising:
a first bracket securing a first data storage device;
a rotating member secured to the first bracket; and
a second bracket securing a second data storage device and rotatably mounted to the rotating member;
wherein the second bracket is rotatable relative to the first bracket.

2. The mounting apparatus of claim 1, wherein first bracket comprises a first front wall, a first rear wall, and a first sidewall, the first front wall is substantially parallel to the first rear wall, and the first front wall is substantially perpendicular to the first sidewall; the rotating member further comprises a mounting piece and a positioning piece, the mounting piece is secured to the first sidewall, and the positioning piece extends out of the first front wall away from the first rear wall along a direction substantially perpendicular to the first rear wall.

3. The mounting apparatus of claim 2, wherein the second bracket comprises a second front wall, a second rear wall, a second sidewall, and a pivoting piece, the second front wall is substantially parallel to the second rear wall, and the second front wall is substantially perpendicular to the second sidewall; the pivoting piece extends from an intersection edge of the second front wall and the second sidewall, the pivoting piece extends away from the second rear wall, and the pivoting piece is rotatably mounted to the positioning piece.

4. The mounting apparatus of claim 3, wherein the rotating member further comprises a connecting piece and a limiting piece extending from the positioning piece; the mounting piece and the positioning piece extend along two opposite directions from opposite edges of the connecting piece; and the limiting piece abuts the pivoting piece when the second bracket is rotated away from the first bracket.

5. The mounting apparatus of claim 4, wherein the limiting piece is substantially perpendicular to the mounting piece and the positioning piece, and the positioning piece is substantially parallel to the mounting piece.

6. The mounting apparatus of claim 3, further comprising a chassis and two installation members secured to the chassis, wherein the first bracket is located between the two installation members; and the first bracket further comprises two protrusions extending from the first sidewall, and the two protrusions are secured to the two installation members.

7. The mounting apparatus of claim 6, wherein each installation member comprises a first installation piece and a second installation piece substantially parallel to the first installation piece, and a cable groove is defined between the first installation piece and the second installation piece receiving a plurality of cables placed therein.

8. The mounting apparatus of claim 7, wherein each protrusion is secured to the second installation piece, and the first installation piece defines a cutout for the plurality of cables passing through.

9. The mounting apparatus of claim 1, wherein the first bracket comprises a mounting plate, which defines a mounting slot; the second bracket comprises a resilient portion, which comprises an operation piece and a latching piece engaged in the mounting slot; and the operation piece is operable to elastically deform the latching piece to disengage from the mounting slot.

10. The mounting apparatus of claim 9, wherein the first bracket further comprises a flange extending from the mounting plate, the second bracket defines an “L” shaped limiting slot, and the flange is engaged in the “L” shaped limiting slot.

11. A mounting apparatus, comprising:
a first bracket securing a first data storage device and comprising a mounting plate;
a rotating member securing to the first bracket; and
a second bracket securing a second data storage device and rotatably mounted to the rotating member;
wherein the mounting plate defines a mounting slot; the second bracket comprises a resilient portion, which comprises an operation piece and a latching piece engaged in the mounting slot; the operation piece is operable to elastically deform the latching piece to disengage from the mounting slot, and the second bracket is rotatable relative to the first bracket when the latching piece disengages from the mounting slot.

12. The mounting apparatus of claim 11, wherein first bracket comprises a first front wall, a first rear wall, and a first sidewall, the first front wall is substantially parallel to the first rear wall, and the first front wall is substantially perpendicular to the first sidewall; the rotating member further comprises a mounting piece and a positioning piece, the mounting piece is secured to the first sidewall, and the positioning piece extends out of the first front wall away from the first rear wall along a direction substantially perpendicular to the first rear wall.

13. The mounting apparatus of claim 12, wherein the second bracket comprises a second front wall, a second rear wall, a second sidewall, and a pivoting piece, the second front wall is substantially parallel to the second rear wall, and the second front wall is substantially perpendicular to the second sidewall; the pivoting piece extends from an intersection edge of the second front wall and the second sidewall, the pivoting piece extends away from the second rear wall, and the pivoting piece is rotatably mounted to the positioning piece.

14. The mounting apparatus of claim 13, wherein the rotating member further comprises a connecting piece and a limiting piece extending from the positioning piece; the mounting piece and the positioning piece extend along two opposite directions from opposite edges of the connecting piece; and the limiting piece abuts the pivoting piece when the second bracket is rotated away from the first bracket.

15. The mounting apparatus of claim 14, wherein the limiting piece is substantially perpendicular to the mounting piece and the positioning piece, and the positioning piece is substantially parallel to the mounting piece.

16. The mounting apparatus of claim 13, further comprising a chassis and two installation members secured to the chassis, wherein the first bracket is located between the two installation members; and the first bracket further comprises two protrusions extending from the first sidewall, and the two protrusions are secured to the two installation members.

17. The mounting apparatus of claim 16, wherein each installation member comprises a first installation piece and a second installation piece substantially parallel to the first installation piece, and a cable groove is defined between the first installation piece and the second installation piece receiving a plurality of cables placed therein.

18. The mounting apparatus of claim 17, wherein each protrusion is secured to the second installation piece, and the first installation piece defines a cutout for the plurality of cables passing through.

19. The mounting apparatus of claim 11, wherein the first bracket further comprises a flange extending from the mounting plate, the second bracket defines a limiting slot, and the flange is engaged in the limiting slot.

20. The mounting apparatus of claim 19, wherein the limiting slot is “L” shaped.
